(19) United States
(12) Patent Application Publication
(10) Pub. No.: US 2010/0308715 A1
(43) Pub. Date: Dec. 9, 2010

(54) ORGANIC PANEL

(75) Inventors: Raiei Chou, Niigata (JP); Tetsuya Katagiri, Niigata (JP)

Correspondence Address: MCDERMOTT WILL & EMERY LLP, 600 13TH STREET, N.W., WASHINGTON, DC, 20005-3096, US

(73) Assignee: Nippon Seiki CO. Ltd

(21) Appl. No.: 12/744,998

(22) PCT Filed: Oct. 17, 2008
(86) PCT No.: PCT/JP2008/068817

§ 371 Date: May 27, 2010

(30) Foreign Application Priority Data
Nov. 29, 2007 (JP) 2007 309377

(51) Int. Cl. H01L 51/30

(52) U.S. Cl. 313/504

(57) ABSTRACT

To provide an organic EL panel having a multiple matrix structure that has a high aperture ratio and can maintain a high display quality. An organic EL panel includes organic EL elements formed by stacking organic layers having at least a light emitting layer between a signal electrode 1 and a scanning electrode 2 that are disposed facing each other so as to cross each other on a substrate. The signal electrode 1, having a plurality of pixel electrodes 1a disposed in a matrix form and wiring electrodes 1b connected to the pixel electrodes 1a, is formed such that a plurality of the pixel electrodes 1a, each connected to a different wiring electrode 1b, adjacent in a direction perpendicular to the scanning electrode 2, configure one unit. The scanning electrode 2 is formed so as to face one unit of the pixel electrodes 1a. The wiring electrodes 1b, being formed between columns of the pixel electrodes 1a, are formed so as to partially curve or bend along the pixel electrodes 1a connected to another wiring electrode 1b.

### RELATED APPLICATIONS

This application is the U.S. National Phase under 35 U.S.C. §371 of International Application No. PCT/JP2008/068817, filed on Oct. 17, 2008, which in turn claims the benefit of Japanese Application No. 2007-309377, filed on Nov. 29, 2007, the disclosures of which Applications are incorporated by reference herein.

### TECHNICAL FIELD

The present invention relates to an organic EL panel using organic EL (electro luminescent) elements, and in particular, relates to a passive drive organic EL panel.

### BACKGROUND ART

As an organic EL element, which is a self light emitting element formed of an organic material, one is known which is formed, for example, by sequentially stacking an anode made of ITO (indium tin oxide) or the like, organic layers having at least alight emitting layer, and a non-translucent cathode made of aluminum (Al) or the like (for example, Patent Document 1).

Also, a passive drive method is known as a drive method of an organic EL panel configured of an organic EL element provided on a translucent substrate. The passive drive organic EL panel is such that a signal electrode is formed in a plurality of linear forms on the translucent substrate, a scanning electrode is formed in a plurality of linear forms so as to cross the signal electrode, and a light emitting portion is formed by the cross-points of the signal electrode and scanning electrode being taken as light emitting pixels, and a plurality of the light emitting pixels being disposed. With such an organic EL panel, a line-sequentially scanned image is displayed in the light emitting portion. Such a passive drive organic EL panel has an advantage in that the manufacture is easy in comparison with that of an active drive type.
Patent Document 1: JP-A-59-194393
Patent Document 2: JP-A-2001-217081

### DISCLOSURE OF THE INVENTION

### Problems that the Invention is to Solve

Also, because of the increase and diversification of information, a further increase in size and higher definition of displays has been demanded in recent years. However, in increasing the light emitting pixels in the passive drive organic EL panel, in particular, the light emitting drive duty ratio increases along with an increase of the scanning electrodes, the time for which voltage is applied to each line of the scanning electrodes decreases, and current and voltage applied to compensate for this increase proportionately. For this reason, there is a problem in that, due to demand restrictions in a drive IC and product specifications, it is difficult to increase the number of light emitting pixels on the scanning electrode side.

As means of decreasing voltage and current in the passive drive to overcome the described problem, there is disclosed in Patent Document 2 a multiple matrix structure wherein signal electrodes are formed in a pectinate electrode pattern having rectangular pixel electrodes and wiring electrodes connected to the pixel electrodes, pixel portions of differing signal electrodes are alternately combined in nested form at cross portions with the scanning electrode, and the cross portions are configured in such a way that one scanning electrode and at least two signal electrodes (pixel portions) cross.

However, as the multiple matrix structure is formed in such a way that the wiring electrodes are formed between the pixel electrodes, and pixel electrodes connected to differing wiring electrodes are combined in nested form, the pixel electrodes in each column of the pixel electrodes are in a zigzag disposition. For this reason, there is a problem in that, when attempting to dispose the light emitting pixels in a straight line, the aperture ratio (the ratio of the actual area of the light emitting pixels to the area of the pixel electrode) decreases. Also, when attempting to increase the aperture ratio, there is a problem in that the light emitting pixels are in a zigzag disposition in the same way as the pixel electrodes, a zigzag effect occurs in the displayed image, and the display quality decreases.

The invention, bearing in mind the heretofore described problems, has an object of providing an organic EL panel with which it is possible, in a multiple matrix structure, to increase the aperture ratio and maintain a high display quality.

### Means for Solving the Problems

In order to solve the heretofore described problems, the invention provides an organic EL panel is characterized by including an organic EL element formed by stacking organic layers having at least a light emitting layer between a signal electrode and a scanning electrode that are disposed to face each other so as to cross each other on a substrate, wherein the signal electrode, having a plurality of pixel electrodes disposed in a matrix form, and wiring electrodes connected to the pixel electrodes, is formed such that a plurality of the pixel electrodes, each connected to a different wiring electrode, adjacent in a direction perpendicular to the scanning electrode configure one unit, wherein the scanning electrode is formed so as to face one unit of the pixel electrodes, and wherein the wiring electrodes, being formed between columns of the pixel electrodes, are formed so as to partially curve or bend along the pixel electrodes connected to another wiring electrode.

Also, the organic EL panel is characterized in that the pixel electrodes have at least one cutaway portion in an end portion, and the wiring electrodes are formed so as to partially curve or bend along the cutaway portion.

Also, the organic EL panel is characterized by including auxiliary electrodes, which are formed on the wiring electrodes, and made of a material of an electrical resistance lower than that of the wiring electrodes.

Also, the organic EL panel is characterized in that the wiring electrodes are wired toward one side of the substrate.

### ADVANTAGE OF THE INVENTION

The invention relates to an organic EL panel, particularly to a passive drive organic EL panel using organic EL elements having a multiple matrix structure that has a high aperture ratio and can maintain a high display quality in a multiple matrix structure.

### BRIEF DESCRIPTION OF THE DRAWINGS

FIG. 1 is an outline view showing the electrode structure of an organic EL panel which is an embodiment of the invention;

FIG. 2 is an enlarged view of the main portion of the organic EL panel;

FIG. 3 is a sectional view of the main portion of the organic EL panel;

FIG. 4 is a diagram showing pixel electrodes of the organic EL panel;

FIG. 5 is an enlarged view of the main portion of an organic EL panel which is a first comparison example;

FIG. 6 is an enlarged view of the main portion of an organic EL panel which is a second comparison example; and

FIG. 7 is a diagram showing other embodiments of the invention.

### DESCRIPTION OF REFERENCE NUMERALS AND SIGNS

1 Signal electrode

1a Pixel electrode

1b Wiring electrode

1c Cutaway portion

2 Scanning electrode

2a Rib

3 Auxiliary electrode

4 Insulation layer

4a Aperture portion

5 Functional organic layer

6 Glass substrate

7 Signal electrode side drive circuit

8 Scanning electrode side drive circuit

### BEST MODE FOR CARRYING OUT THE INVENTION

Hereafter, a description will be given, based on the attached drawings, of an organic EL panel, which is an embodiment of the invention.

The organic EL panel of the embodiment includes, as its basic configuration, an organic EL element formed by stacking functional organic layers having at least a light emitting layer between a signal electrode and a scanning electrode that are disposed to face each other so as to cross each other on a translucent glass substrate.

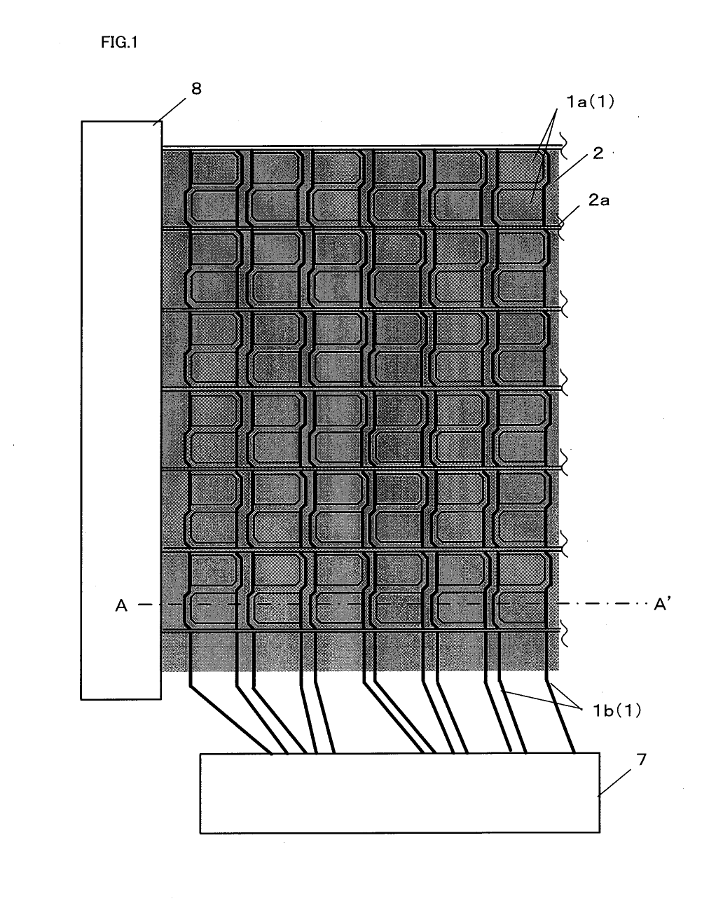

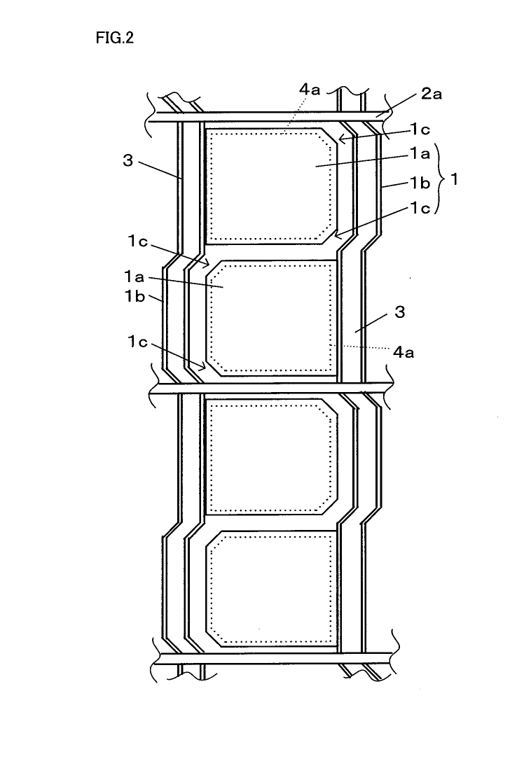

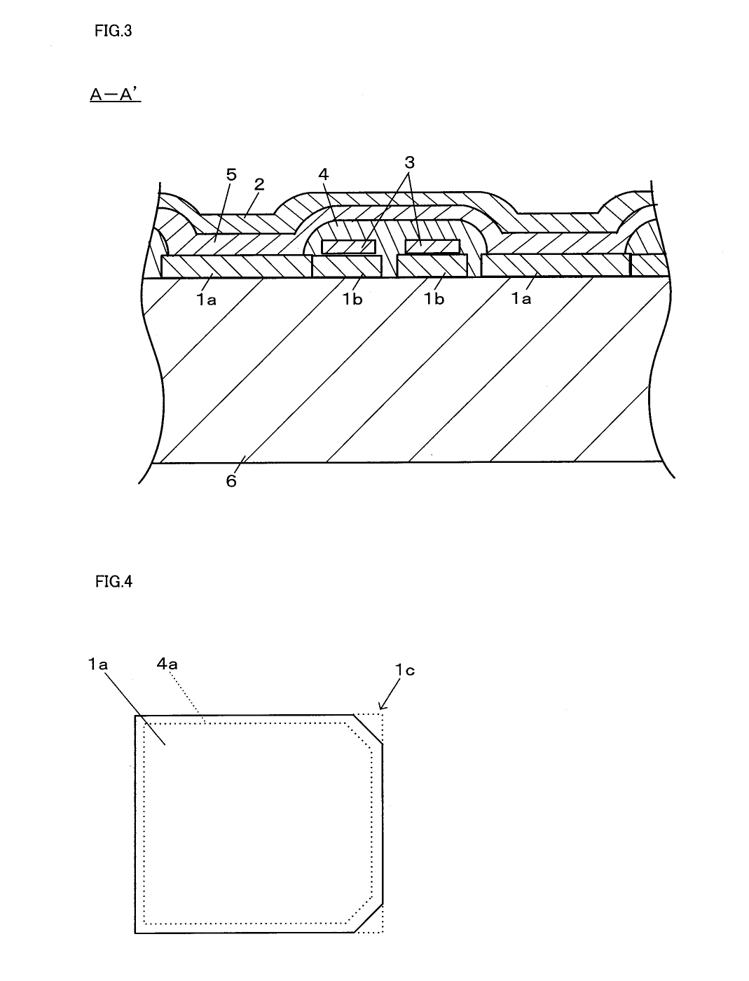

FIGS. 1 and 2 show an electrode structure of the organic EL panel. The organic EL panel includes a signal electrode 1, which has pixel electrodes 1a and wiring electrodes 1b and configures an anode, a scanning electrode 2, which is formed so as to cross the signal electrode 1 and configures a cathode, and auxiliary electrodes 3 formed on the wiring electrodes 1b. In the organic EL panel, the places where the pixel electrodes 1a and scanning electrode 2 face (cross) are used as light emitting pixels (the organic EL elements), a light emitting portion is formed by disposing a plurality of the light emitting pixels in a matrix. An insulation layer is formed below the scanning electrode 2, excepting the portions configuring the light emitting pixels, to prevent a short circuiting of the signal electrode 1 and scanning electrode 2. In FIG. 3 a sectional view of the main portion of the organic EL panel, 4 is the short circuit preventing insulation layer, 5 is the organic layers including at least a light emitting layer, and 6 is a glass substrate.

The signal electrode 1 has a plurality of the pixel electrodes 1a disposed in a matrix form, and the wiring electrodes 1b connected to the pixel electrodes 1a. The signal electrode 1 is formed in such a way that, with a plurality (two in the embodiment) of pixel electrodes 1a adjacent to one another column-wise (in a direction perpendicular to the scanning electrode) as one unit, each of the pixel electrodes 1a in one unit is connected to a different wiring electrode 1b. That is, two lines of the signal electrode 1 so configure one column of the light emitting pixels.

The pixel electrodes 1a are formed by a translucent conductive material such as ITO (indium tin oxide) being formed in layer form on the glass substrate by a sputtering method or the like, and patterned into a predetermined shape by, for example, a photolithography method. Also, the pixel electrodes 1a are formed in a substantially rectangular shape and each have a cutaway portion 1c in an end portion. FIG. 4 shows only the pixel electrode 1a. The cutaway portion 1c is a portion of the end of the pixel electrode 1a which is obliquely removed. As the shape of the light emitting pixel to be shown through an aperture portion 4a of the insulation layer 4 is also partly missing in accordance with the cutaway portion 1c, it is preferable that the cutaway portion 1c is of a size that is not viewable to a user. For example, it is preferable that the vertical and horizontal lengths of the cutaway portion 1c are 0.2 mm or less, or ⅓ or less of the length of the pixel electrode 1a. Also, in the event that the organic EL panel is used in a portable instrument which is seen from a close distance, it is more preferable that the vertical and horizontal lengths are 0.07 mm or less. Also, practically, it has been confirmed that a cutaway of 0.003 mm or more is necessary.

The wiring electrodes 1b are made of, for example, the same material as that of the pixel electrodes 1a and are formed together with the pixel electrodes 1a. The wiring electrodes 1b are wired between the respective columns of the pixel electrodes 1a so as to cross the scanning electrode 2, and are connected alternately to each pixel electrode 1a in each column of the pixel electrodes 1a. Also, the wiring electrodes 1b are formed so as to partially curve or bend in order to avoid the pixel electrodes 1a connected to another wiring electrode 1b in each column of the pixel electrodes 1a. Then, the curved places or bent places of the wiring electrodes 1b are formed along the cutaway portions 1c of the pixel electrodes 1a. Also, the wiring electrodes 1b, each being wired toward one side of the glass substrate, are connected to a signal electrode side drive circuit 7. The signal electrode side drive circuit 7 supplies power to the signal electrode 1 in order to display a predetermined image in accordance with sequential scans of the scanning electrode 2 by a scanning electrode side drive circuit 8 to be described hereafter.

The scanning electrode 2 is formed by forming a layer of a metallic conductive material with a conductivity higher than that of the signal electrode 1, such as aluminum (Al), magnesium (Mg), cobalt (Co), lithium (Li), gold (Au) , zinc (Zn), or an alloy thereof, using a deposition method or the like, and separating the layer into a plurality of linear forms by ribs 2a configured of an insulating resin material formed in linear form. Each scanning electrode 2 is formed so as to cross the signal electrode 1, and to face one unit of the pixel electrodes 1a in the columnar direction. For this reason, although the insulation layer 4 is formed between the pixel electrodes 1a in one unit, the ribs 2a for separating the scanning electrode 2 are not formed in the upper portion thereof. Also, each scanning electrode 2 is connected to the scanning electrode side drive circuit 8. The scanning electrode side drive circuit 8 sequentially scans the scanning electrodes 2 at a predetermined duty ratio.

The auxiliary electrodes 3 are formed by a material of an electrical resistance lower than that of the material configuring the pixel electrodes 1a, such as chrome (Cr), being formed in a layer form on the glass substrate by a sputtering method or the like, and patterned into a predetermined shape by, for example, a photolithography method. The auxiliary electrodes 3 formed on the respective wiring electrodes 1b, so as to partially curve or bend along the cutaway portions 1c of the pixel electrodes 1a, in the same way as the shape of the wiring electrodes 1b. The auxiliary electrodes 3 may be segmentalized into a plurality, portions excepting the connecting places of the wiring electrodes 1b and the pixel electrodes 1a.

Such organic EL panel is of a so-called multiple matrix structure, and two lines of light emitting pixels are illumination controlled when scanning of one line of the scanning electrode 2 is carried out.

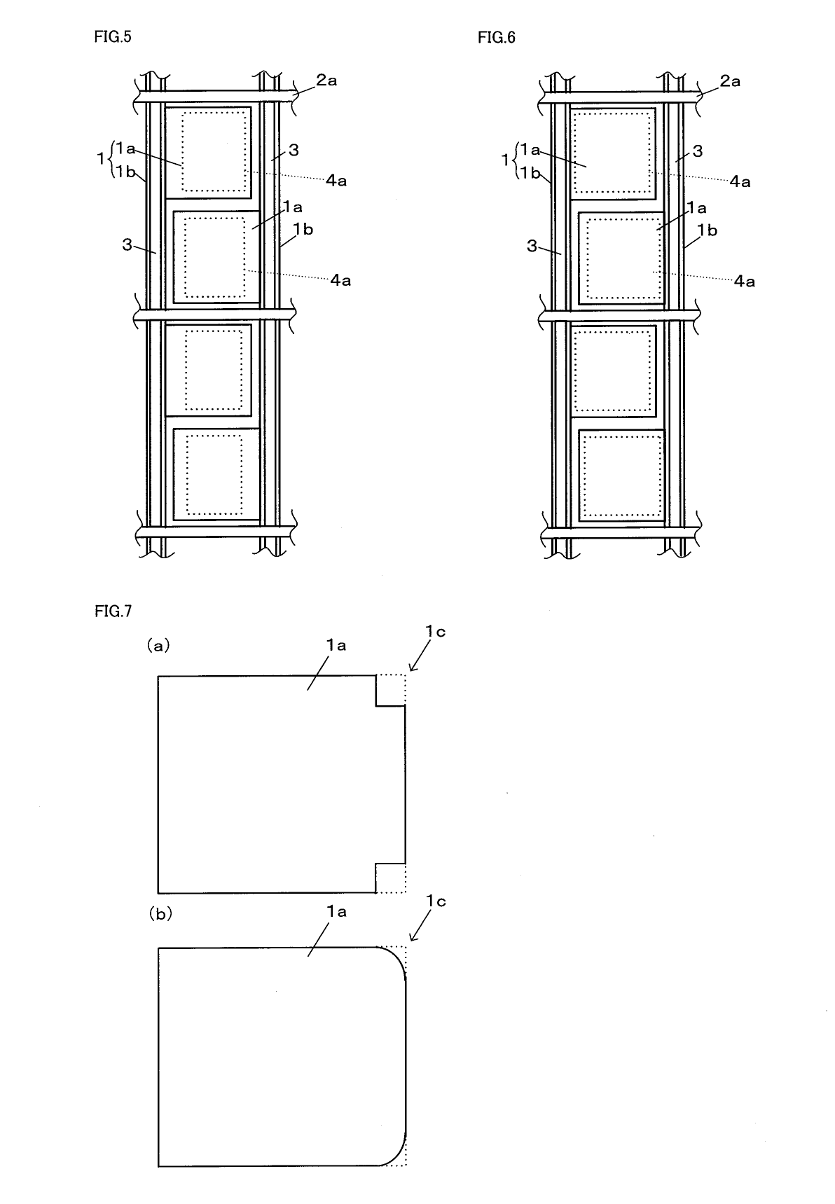

In the organic EL panel of the embodiment, it is possible, by forming the wiring electrodes 1b so as to partially curve or bend along the pixel electrodes 1a connected to another wiring electrode 1b, to dispose the pixel electrodes 1a overlapping linearly, rather than in the heretofore known zigzag disposition. FIGS. 5 and 6 show first and second comparison examples of the heretofore known pixel electrodes 1a in a zigzag disposition. In the first comparison example of FIG. 5, since the light emitting pixels shown through the aperture portions 4a of the insulation layer 4 are disposed in a straight line, the peripheral portions of the pixel electrodes 1a, which do not overlap each other, cannot be used as light emitting pixels and thus the aperture ratio is reduced. Also, in the second comparison example of FIG. 6, as a result of increasing the aperture ratio, the light emitting pixels are in a zigzag disposition corresponding to the positional misalignment of the pixel electrodes 1a, and a zigzag effect occurs in the displayed image. As opposed to this, in the embodiment, as the pixel electrodes 1a are disposed in a straight line so as to overlap each other in each column, it is possible to dispose the light emitting pixels in a straight line even in increasing the aperture ratio, including the peripheral portions of the pixel electrodes 1a, and it is possible to maintain a high display quality. In particular, by providing the cutaway portions 1c in the end portion of the pixel electrodes 1a, and forming the wiring electrodes 1b so as to curve or bend along the cutaway portions 1c, there is no need to leave an unnecessary interval between the pixel electrodes 1a, and it is possible to maintain a high display quality.

In the embodiment, the cutaway portion 1c is formed by removing the end portion of the pixel electrode 1a in a substantially triangular shape, but the shape of the cutaway portions 1c is not limited to this, and the shapes as shown in FIG. 7 may also be adopted. In FIG. 7(a), the cutaway portions 1c are of a rectangular shape, and in FIG. 7(b), the cutaway portions 1c are provided by removing the end portion of the pixel electrodes 1a in an arc shape. In the embodiment, the cutaway portions 1c are provided in only one portion of the end portions, but they may of course be provided in all the end portions.

Also, in the embodiment, one unit is configured of two pixel electrodes 1a, and each pixel electrode 1a in one unit is connected to a different wiring electrode 1b, but the invention may also be applied to the case of one unit configured of three or more pixel electrodes 1a. That is, a configuration may also be adopted in which three or more pixel electrodes connected to different wiring electrodes are disposed facing one line of the scanning electrode. It is also possible to obtain the same kind of advantage by applying the invention to such configuration.

### INDUSTRIAL APPLICABILITY

The invention relates to an organic EL panel using organic EL elements, and is particularly preferable in a passive drive organic EL panel having a multiple matrix structure.

1. An organic EL panel, characterized by including:
organic EL elements formed by stacking organic layers having at least a light emitting layer between a signal electrode and a scanning electrode that are disposed facing each other so as to cross each other on a substrate, wherein
the signal electrode, having a plurality of pixel electrodes disposed in a matrix form and wiring electrodes connected to the pixel electrodes, is formed such that a plurality of the pixel electrodes, each connected to a different wiring electrode, adjacent in a direction perpendicular to the scanning electrode, configure one unit, wherein
the scanning electrode is formed so as to face one unit of the pixel electrodes, and wherein
the wiring electrodes, being formed between columns of the pixel electrodes, are formed in such away as to partially curve or bend along the pixel electrodes connected to another wiring electrode.

2. The organic EL panel according to claim 1, characterized in that
the pixel electrodes have at least one cutaway portion in an end portion, and
the wiring electrodes are formed so as to partially curve or bend along the cutaway portion.

3. The organic EL panel according to claim 1, characterized by including:
auxiliary electrodes which are formed on the wiring electrodes and made of a material of an electrical resistance lower than that of the wiring electrodes.

4. The organic EL panel according to claim 1, characterized in that
the wiring electrodes are wired toward one side of the substrate.
